(19) United States
(12) Patent Application Publication
(10) Pub. No.: US 2008/0074294 A1
(43) Pub. Date: Mar. 27, 2008

(54) SYSTEM FOR CONTROLLING KEYBOARD

(75) Inventors: Chi-Hsin Lin, Taipei City (TW); Yi-Hung Shen, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: COMPAL ELECTRONICS, INC., Taipei City (TW)

(21) Appl. No.: 11/671,474

(22) Filed: Feb. 6, 2007

(30) Foreign Application Priority Data
Sep. 26, 2006 (TW) 95135499

(51) Int. Cl. H03M 11/00

(52) U.S. Cl. 341/26

(57) ABSTRACT

A system for controlling a keyboard is provided. The present invention adopts a structure integrating a scanning unit into a keyboard device. After scanning the keyboard, a key matrix position of a pressed key is sent to a control device. By looking up a programmable matrix table stored in the control device, a corresponding scan code is found out. Therefore, a circuit disposed between the keyboard device and the control device is simplified and the manufacturing cost can be reduced.

### CROSS-REFERENCE TO RELATED APPLICATION

This application claims the priority benefit of Taiwan application serial no. 95135499, filed Sep. 26, 2006. All disclosure of the Taiwan application is incorporated herein by reference.

### BACKGROUND OF THE INVENTION

1. Field of the Invention

The present invention relates to a system for controlling a keyboard. More particularly, the present invention relates to a system for controlling a keyboard that integrates a scan unit into a keyboard device.

2. Description of Related Art

With the coming of computer era, computers have become an indispensable tool for modern people. No matter in terms of word processing, websites browsing, data storage, or multimedia applications, computer science and technology bring convenience and fun, thus continuously influencing the life of modern people. Among various peripheral equipments of computers, keyboards are one of the most important input devices. People can input instructions through keyboards to operate computers to execute various functions.

FIG. 1 is a block diagram of a conventional system for controlling a keyboard built in a notebook computer. Referring to FIG. 1, in the system for controlling a keyboard 100, when a user inputs by using an input unit 111 on a keyboard device 110, a control signal is generated to inform an interrupt unit 129 in a control device 120 to temporarily stop the operations currently performed by a processing unit 123. A scan unit 121 in the control device 120 repeatedly performs scan input and scan output operations on the keyboard device 110. After the scan input and output operations, the scan unit 121 transmits a scan signal to the processing unit 123, and then the processing unit 123 looks up a variable matrix table 125 by the use of an encoding unit 122, and converts the scan signal into a scan code. The output interface 127 then outputs the scan code to the system host of the notebook computer to perform subsequent operations.

However, in the system for controlling a keyboard 100, an 8-pin joint is required between the keyboard device 110 and the control device 120 for performing the scan input operation, and further a 16-pin joint is also required for performing the scan output operation. Therefore, the circuit between the keyboard device 110 and the control device 120 is very complicated, which causes an increase of cost for circuit layout. In addition, the processing unit 123 must temporally interrupt operations of other input/output devices, so as to control the scan unit 121 to perform scanning operation.

In another system for controlling a keyboard, the keyboard device is disposed outside a computer and connected to the computer through a personal system/2 (PS/2) interface. FIG. 2 is a block diagram of a conventional system for controlling a keyboard of an externally connected keyboard device. Referring to FIG. 2, in the system for controlling a keyboard 200 which bases on an externally connected keyboard device, when the user presses the input unit 211 in the keyboard device 210, the scan unit 215 in the keyboard controller 213 continuously performs scan input and scan output operations, and the encoding unit 217 converts the scan signal sent out by the input unit 211 into a scan code in accordance with an unchanged matrix table 219. Then, the scan code is transmitted to the control device 220 via the output interface 212. In this system, the scan unit 215 is disposed in the keyboard controller 213 of the keyboard device 210, which simplifies the circuit between the keyboard device 210 and the control device 220 but limits the flexibility of the keyboard device 210 in use due to the fixed matrix table 219.

### SUMMARY OF THE INVENTION

Accordingly, the present invention is directed to a system for controlling a keyboard, which simplifies the circuit between the keyboard device and the control device by means of changing the layout of elements disposed between the keyboard device and the control device, so as to achieve the purpose of reducing the manufacturing cost.

As embodied and broadly described herein, a system for controlling a keyboard including a keyboard device and a control device disposed in a system host is provided. The keyboard device has an input unit, a scan unit, and a first output interface. The input unit is used to provide a control signal. The scan unit is coupled to the input unit, and is used to perform a scanning operation of the keyboard device according to the control signal and provide a scan signal. The first output interface is coupled to the scan unit, and is used to output the scan signal. The control device includes an input interface, a storage unit, a processing unit, and a second output interface. The input interface is connected to the first output interface of the keyboard device for receiving the scan signal. The storage unit is used to store a key matrix table. The processing unit is coupled to the input interface and the storage unit, and is used to determine a scan signal by way of looking up the key matrix table and convert the scan signal into a corresponding scan code. The second output interface is coupled to the processing unit, and is used to output the scan code to the system host.

In the system for controlling a keyboard according to a preferred embodiment of the present invention, the scan signal includes a key matrix position of a pressed key.

In the system for controlling a keyboard according to a preferred embodiment of the present invention, the key matrix table includes key values corresponding to each of the key matrix positions.

In the system for controlling a keyboard according to a preferred embodiment of the present invention, the processing unit finds out the key value corresponding to the scan signal according to the key matrix table, and converts it into the scan code.

In the system for controlling a keyboard according to a preferred embodiment of the present invention, the key matrix table is a programmable variable matrix table.

In the system for controlling a keyboard according to a preferred embodiment of the present invention, the scan signal is a serial signal.

In the system for controlling a keyboard according to a preferred embodiment of the present invention, the first output interface of the keyboard device and the input interface of the control device include one of a personal system/2 (PS/2) interface, a serial peripheral interface (SPI), and a universal serial bus (USB) interface.

In the system for controlling a keyboard according to a preferred embodiment of the present invention, the second output interface includes an industry standard architecture (ISA) interface or a peripheral controller interface (PCI).

In the system for controlling a keyboard according to a preferred embodiment of the present invention, the control device includes an input/output card (I/O card) disposed in a system host.

In the system for controlling a keyboard according to the present invention, the scan unit is integrated into the keyboard device, and converts the input control signal into a scan signal and then outputs it to the control device, so as to perform subsequent operations. As such, the circuit between the keyboard device and the control device can be simplified. In addition, the key matrix table stored in the control device has a programmable characteristic, such that the key values corresponding to the key matrix positions can be varied to increase the flexibility of the use of the keyboard device.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram of a conventional system for controlling a keyboard built in a notebook computer.

FIG. 2 is a block diagram of a conventional system for controlling a keyboard of an externally connected keyboard device.

FIG. 3 is a block diagram of a system for controlling a keyboard according to a preferred embodiment of the present invention.

FIG. 4 is a flow chart of the operation of a system for controlling a keyboard built in the notebook computer according to a preferred embodiment of the present invention.

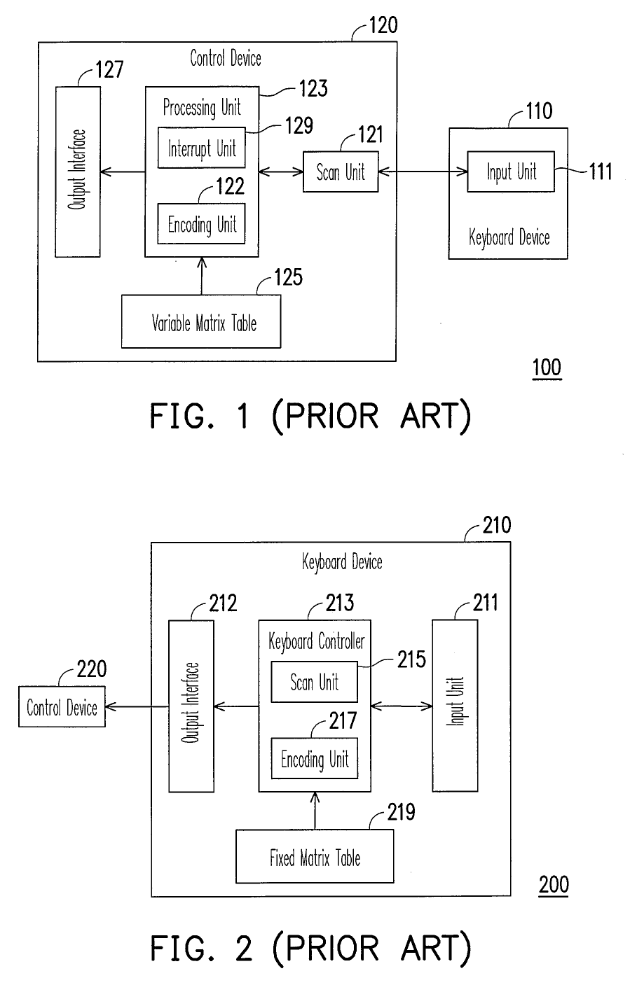

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Generally speaking, the circuit capable of supporting the scan input and scan output operations is very complicated. If the scan unit responsible for scanning operation is disposed in the keyboard device, the cost for circuit between the keyboard device and the control device can be reduced. In addition, if the key matrix table can be stored in the control device, the flexibility of the use of the keyboard device can be enhanced. The present invention proposes a system for controlling a keyboard based upon the above concepts.

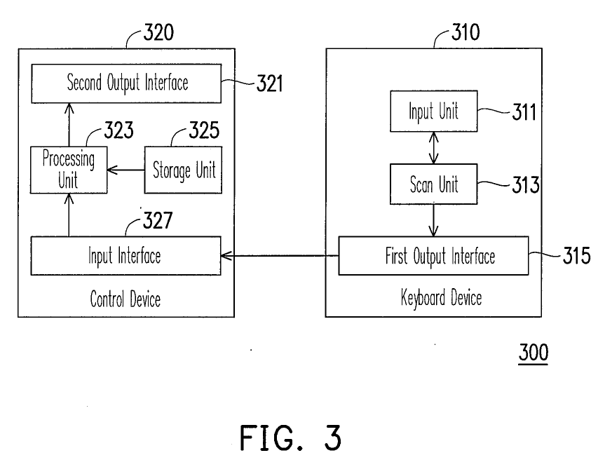

FIG. 3 is a block diagram of a system for controlling a keyboard according to a preferred embodiment of the present invention. Referring to FIG. 3, the system for controlling a keyboard 300 includes a keyboard device 310 and a control device 320. The keyboard device 310 includes an input unit 311, a scan unit 313, and a first output interface 315. The input unit 311 is used for providing a control signal. The scan unit 313 connected to the input unit 311 performs a scanning operation on the keyboard device 310 according to the control signal, and provides a corresponding scan signal. The scan signal is then output via the first output interface 315.

The control device 320 disposed on the system host includes a second output interface 321, a processing unit 323, a storage unit 325, and an input interface 327. The input interface 327 is connected to the first output interface 315 of the keyboard device 310 for receiving the scan signal transmitted by the first output interface 315. In this embodiment, the first output interface 315 and the input interface 327 include, for example, a personal system/2 (PS/2) interface, a serial peripheral interface (SPI), or a universal serial bus (USB) interface, which is not limited herein. The processing unit 323, connected to the input interface 327 and the storage unit 325, finds out a scan code corresponding to the scan signal by means of looking up the key matrix table stored in the storage unit 325, and then the scan code is output to the system host via the second output interface 321.

In the above embodiment, the control device 320 is, for example, disposed on an input/output card (I/O card) of the system host. The second output interface 321 used to output the scan code to the system host includes, for example, an industry standard architecture (ISA) interface or a peripheral controller interface (PCI), and the like, which is not limited herein.

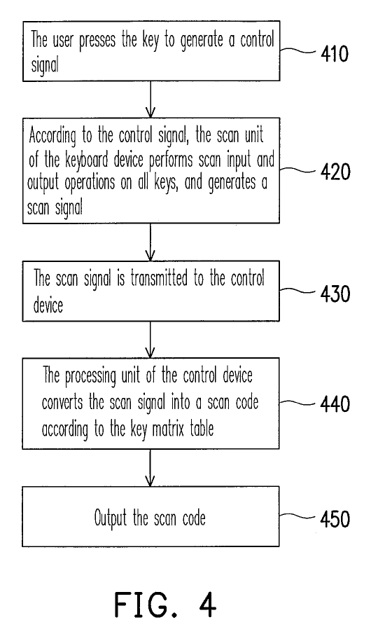

In order to make the operation flow of the system for controlling a keyboard in the present invention more apparent, another embodiment is illustrated in detail below. FIG. 4 is a flow chart of the operation of a system for controlling a keyboard built in the notebook computer according to a preferred embodiment of the present invention. In the system for controlling the keyboard in this embodiment, the input unit of the keyboard device includes, for example, a plurality of keys, and the system for controlling a keyboard is used to detect the pressed key on the keyboard device and converts it into a corresponding scan code for the central processing unit (CPU) of the notebook computer to perform the subsequent operations.

Referring to FIG. 4, when the user presses the key on the input unit of the keyboard device, a control signal is triggered (Step 410). After the keyboard device receives the control signal, the scan unit built in the keyboard device performs the scan output and scan input operations on all keys, and generate a scan signal corresponding to the pressed key (Step 420). For example, all the keys on the input unit are generally arranged in a matrix, and the scan signal records the position of the above key in the key matrix. Then, in Step 430, the scan unit on the keyboard device transmits the key matrix position to the control device of the notebook computer via an output interface.

In this embodiment, the key matrix table stored in the storage unit of the control device is, for example, a programmable variable matrix table recording the key values corresponding to each of the key matrix positions. Therefore, after the control device receives the key matrix position sent by the keyboard device via the input interface, in Step 440, the processing unit in the control device finds out the key value corresponding to the above key matrix position by means of looking up the key matrix table, and converts it into the scan code. In Step 450, the scan code is output to, for example, the central processing unit (CPU) of the notebook computer through the output interface in the control device, and then the CPU performs corresponding operations.

It should be noted that the key matrix table recording the key values corresponding to the key matrix positions is, for example, a programmable variable matrix table. Thus, users or persons in this art may modify the recorded key values by means of software control according to their habits or demands, so as to change the meaning represented by the key corresponding to the key matrix position. For example, the user can set the key value corresponding to each hot key on the keyboard personally through an application for modifying set values of a computer system, thereby changing the functions executed when pressing the hot key.

To sum up, the system for controlling a keyboard of the present invention integrates the scan unit into the keyboard device, and directly transfers the key matrix position to the control device after the scanning operation, so as to reduce the circuit between the keyboard device and the control device, thereby reducing the manufacturing cost. In addition, the key matrix table stored in the control device has the programmable characteristic, and thus the key value corresponding to the key matrix position can be modified.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A system for controlling a keyboard, comprising:
a keyboard device, comprising:
an input unit, for providing a control signal;
a scan unit, coupled to the input unit, for scanning the keyboard device according to the control signal and providing a scan signal;
a first output interface, coupled to the scan unit, for outputting the scan signal;
a control device, disposed in a system host, comprising:
an input interface, connected to the first output interface of the keyboard device, for receiving the scan signal;
a storage unit, for storing a key matrix table;
a processing unit, coupled to the input interface and the storage unit, for determining the scan signal by means of looking up the key matrix table and converting the scan signal into a corresponding scan code; and
a second output interface, coupled to the processing unit, for outputting the scan code to the system host.

2. The system for controlling the keyboard as claimed in claim 1, wherein the scan signal comprises a key matrix position of a pressed key.

3. The system for controlling the keyboard as claimed in claim 2, wherein the key matrix table comprises a plurality of key values corresponding to each of the key matrix positions.

4. The system for controlling the keyboard as claimed in claim 3, wherein the processing unit finds out the key values corresponding to the scan signal according to the key matrix table, and converts the key value into the scan code.

5. The system for controlling the keyboard as claimed in claim 1, wherein the key matrix table is a programmable variable matrix table.

6. The system for controlling the keyboard as claimed in claim 1, wherein the scan signal is a serial signal.

7. The system for controlling the keyboard as claimed in claim 1, wherein the first output interface of the keyboard device and the input interface of the control device comprise one of a personal system/2 (PS/2) interface, a serial peripheral interface (SPI), and a universal serial bus (USB) interface.

8. The system for controlling the keyboard as claimed in claim 1, wherein the second output interface comprises an industry standard architecture (ISA) interface or a peripheral controller interface (PCI).

9. The system for controlling the keyboard as claimed in claim 1, wherein the control device comprises an input/output card (I/O card) disposed on the system host.
